(19) United States
(12) Patent Application Publication
(10) Pub. No.: US 2018/0292694 A1
(43) Pub. Date: Oct. 11, 2018

(54) A METHOD FOR IMPROVING THE MASK STRIPPING EFFICIENCY OF AN ARRAY SUBSTRATE, AN ARRAY SUBSTRATE AND A DISPLAY PANEL

(71) Applicant: Shenzhen China Star Optoelectronics Technology Co., Shenzhen, Guangdong (CN)

(72) Inventors: Mian ZENG, Shenzhen, Guangdong (CN); Xiaodi LIU, Shenzhen, Guangdong (CN)

(73) Assignee: Shenzhen China Star Optoelectronics Technology Co. , Ltd., Shenzhen, Guangdong (CN)

(21) Appl. No.: 15/540,948

(22) PCT Filed: May 10, 2017
(86) PCT No.: PCT/CN2017/083692

§ 371 Date: Jun. 29, 2017

(30) Foreign Application Priority Data
Apr. 11, 2017 (CN) 201710233398.7

(51) Int. Cl. G02F 1/1337; G03F 7/42

(52) U.S. Cl. CPC G02F 1/13378; G02F 2001/133354; G03F 7/427; G03F 7/422

(57) ABSTRACT

A method for improving the mask stripping efficiency of an array substrate, an array substrate and a display panel is disclosed in the present application. The method includes forming a patterned mask on the non-display region; etching the portion of the non-display region not covered by the patterned mask, depositing transparent electrode layers to form a patterned first transparent electrode layer and a patterned second electrode layer, respectively on the surface of the patterned mask and the surface of the etched non-display region; and removing the patterned mask. The mask stripping efficiency of the array substrate can be improved by the method, thereby improving the manufacturing efficiency of the display panel.

### FIELD OF THE INVENTION

The present application relates to a display panel technology field and, more particularly, to a method for improving the mask stripping efficiency of an array substrate, an array substrate and a display panel.

### BACKGROUND OF THE INVENTION

The three masks process technology is a new technology that can greatly reduce the number of array substrates for the display panel. This technology not only saves the manufacturing cost of the array substrate, but also shortens the time of the manufacturing process and improves the production capacity. The stripping process in the three-mask process is to form a patterned mask and then form a transparent electrode layer on the mask. Finally, the mask and the transparent electrode layer on the mask are removed by the stripper to form a patterned transparent electrode layer.

The stripping rate of the mask is related to the entire area of the stripped mask, the larger the entire area of the mask to be stripped, the longer the time that the stripper infiltrating the mask and the longer the stripping time.

The inventors of the present application have found from the long-term research and development, in the conventional technology, since the patterned transparent electrode layer need to be formed on the display region of the array substrate, and the transparent electrode layer does not need to be retained in the non-display region, therefore, a patterned mask is formed on the surface of the display region, and a monolithic non-patterned mask is directly formed in the non-display region. However, when the mask is removed by the stripper, because of the related larger area of the non-patterned mask in the non-display region, the time of the stripper completely infiltrating the non-patterned mask is much longer than the time of infiltrating the patterned mask in the display region, resulting in a decrease mask stripping efficiency of the entire array substrate, thereby reducing the manufacturing efficiency of the display panel.

### SUMMARY OF THE INVENTION

The technical problem that is mainly solved in the present application is to provide a method for improving the mask stripping efficiency of an array substrate, an array substrate and a display panel to improve the mask stripping efficiency during the fabrication of the array substrate, thereby improving the manufacturing efficiency of the display panel.

In order to solve the above-mentioned technical problem, a technical solution adopted in the present application is to provide a method for improving the mask stripping efficiency of an array substrate. The array substrate includes a display region and a non-display region disposed around the display region; a passivation layer and an insulating layer are disposed on the upper surface of the non-display region from top to bottom, the method includes: forming a patterned mask on the non-display region; etching the passivation layer or the passivation layer and the insulating layer not covered by the patterned mask, depositing transparent electrode layers to form a patterned first transparent electrode layer and a patterned second electrode layer, respectively on the surface of the patterned mask and the surface of the etched passivation layer or the etched insulating layer; and infiltrating the surface of the mask not covered by the patterned first transparent electrode layer and the patterned second electrode layer by a stripper to remove the patterned mask.

In order to solve the above-mentioned technical problem, another technical solution adopted in the present application is to provide a method for improving the mask stripping efficiency of the array substrate. The array substrate includes a display region and a non-display region disposed around the display region, the method includes: forming a patterned mask on the non-display region; etching the portion of the non-display region not covered by the patterned mask, depositing transparent electrode layers to form a patterned first transparent electrode layer and a patterned second electrode layer, respectively on the surface of the patterned mask and the surface of the etched non-display region; and removing the patterned mask.

In order to solve the above-mentioned technical problem, another technical solution adopted in the present application is to provide an array substrate. The array substrate includes a display region and a non-display region disposed around the display region; an etching groove is disposed in the non-display region, a transparent electrode layer is embedded in the etching groove, and the profile of the etching groove is defined by the patterned mask.

In order to solve the above-mentioned technical problem, another technical solution adopted in the present application is to provide a display panel. The display panel includes: a first substrate, a second substrate, and a liquid crystal layer, wherein the first substrate and/or the second substrate is the array substrate mentioned above; wherein the liquid crystal layer is located between the first substrate and the second substrate, and the transmittance of a backlight is adjusted under the control of the first substrate and the second substrate.

The advantageous effect of the embodiment of the present application is that, compared to the conventional technology, the present embodiment first forms a patterned mask in the non-display region and etches the non-display region portion where the patterned mask is not covered, and then depositing and forming a patterned first transparent electrode layer and a patterned second electrode layer on the surface of the patterned mask and the etched surface of the non-display region, respectively, and finally removing the patterned mask. The embodiment of the present application takes a mask to be stripped off as a patterned mask, such that the stripper can passed through the patterned mask through all sides of the patterned mask, rather than just through the peripheral sides of the patterned mask, and infiltrate it. By the way, it can significantly increase the stripping efficiency of the mask of the array substrate, and improve the manufacturing efficiency of the display panel.

### BRIEF DESCRIPTION OF THE DRAWINGS

In order to more clearly illustrate the embodiments of the present application or conventional technology, the following FIG.s will be described in the embodiments are briefly introduced. It is obvious that the drawings are merely some embodiments of the present application, those of ordinary skill in this field can obtain other FIG.s according to these FIG.s without paying the premise.

FIG. 1 is a schematic flow diagram of a method for improving the mask stripping efficiency of an array substrate of the present application;

FIG. 2 is a schematic flow diagram of a mask stripping process of the array substrate of one embodiment of the present application;

FIG. 3 is a schematic structural view of a patterned non-display region of one embodiment illustrated in the embodiment of FIG. 2;

FIG. 4 is a schematic structural view of a patterned mask of one embodiment of the present application;

FIG. 5 is a schematic structural view of a patterned mask of another embodiment of the present application;

FIG. 6 is a schematic view of an array substrate of one embodiment of the present application; and

FIG. 7 is a schematic structural view of a display panel of one embodiment of the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts acquired should be considered within the scope of protection of the present application.

Specifically, the terminologies in the embodiments of the present application are merely for describing the purpose of the certain embodiment, but not to limit the invention.

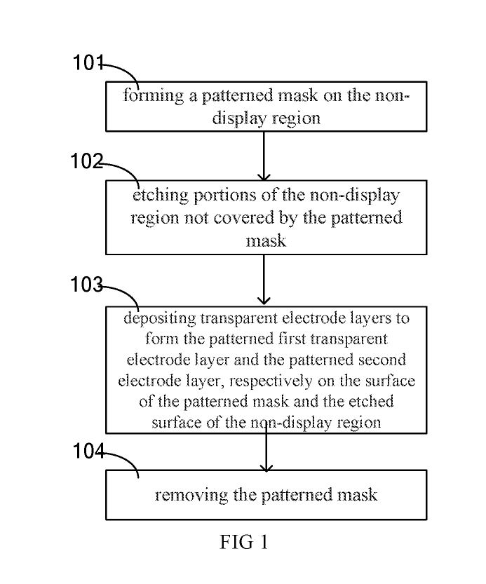

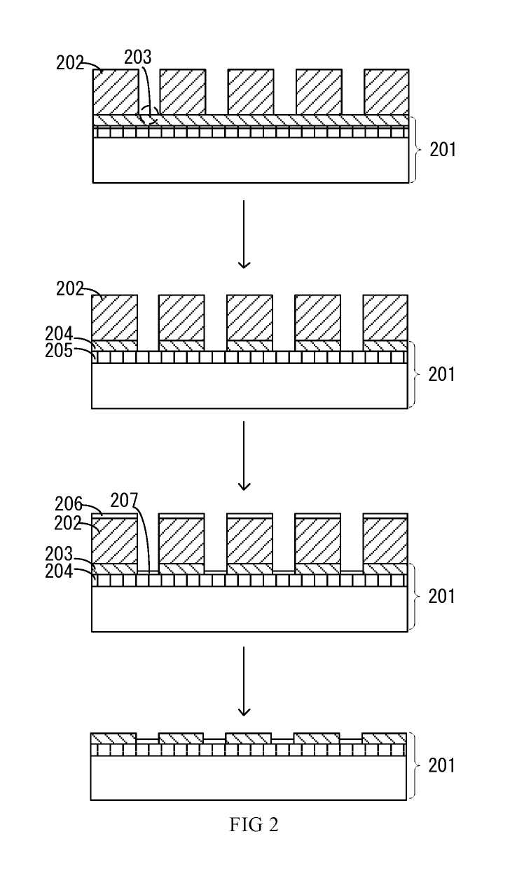

Referring to FIGS. 1 and 2, FIG. 1 is a schematic flow diagram of a method for improving the mask stripping efficiency of an array substrate of the present application; FIG. 2 is a schematic flow diagram of a mask stripping process of the array substrate of one embodiment of the present application. The array substrate of the present application includes a display region and a non-display region disposed around the display region. The present embodiment includes the following steps:

Step 101: forming a patterned mask 202 on the non-display region 201 (as illustrated in the first figure in FIG. 2).

During the fabrication of the array substrate, the mask 202 mainly provides an etch template for forming each patterned layers, the pattern of which is dependent on the pattern of the respective layers.

In an application scenario, the mask is a photoresist. The photoresist is a mixed liquid sensitive to light and includes three main components of a photosensitive resin, a sensitizer, and a solvent. It has good fluidity and coverage. Of course, in other applications, other materials can be used instead of photoresist.

Step 102: etching portions of the non-display region 203 not covered by the patterned mask 202. It can be understood that the non-display region 201 is etched into a patterned non-display region 201 (as illustrated in the second figure in FIG. 2). In one application scenario, the pattern of the mask 202 of this embodiment is completely overlapped and coincided with the pattern of the non-display region 201.

Etching is a selectively removal of a portion of the layer that is not covered by the resist by chemical, physical or simultaneous use of chemical and physical methods, thereby to obtain a pattern in the layer and the pattern is exactly the same with the resist layer. The Etching technology is mainly divided into dry etching and wet etching. The dry etching mainly uses the reaction gas and the plasma to perform the etching; and the wet etching mainly uses the chemical reagent to have chemical reactions with the etched material to perform the etching. The present embodiment does not limit the specific type of etching.

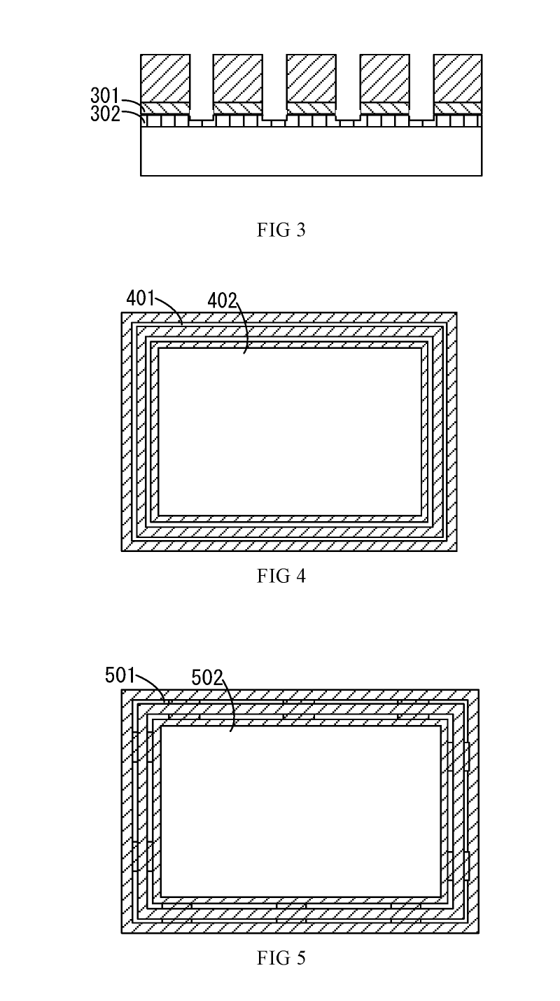

Alternatively, the upper surface of the non-display region 201 of the present embodiment is provided with a passivation layer 204 and an insulating layer 205 from top to bottom, and the passivation layer 204 is located between the insulating layer 205 and the patterned mask 202. In one application scenario, the passivation layer 204 can be etched into a patterned passivation layer 204. In other application scenarios, the passivation layer 301 and the insulating layer 302 can be etched into a patterned passivation layer 301 and a patterned insulating layer 302 (as illustrated in FIG. 3).

Step 103: depositing transparent electrode layers 206, 207 to form the patterned first transparent electrode layer 206 and the patterned second electrode layer 207, respectively on the surface of the patterned mask 202 and the etched surface of the non-display region 201 (as illustrated in the third figure in FIG. 2).

Alternatively, the pattern thickness of the patterned passivation layer 204 of the present embodiment, or the pattern thickness of the patterned passivation layer 301 and the patterned insulating layer 302 are not smaller than the thickness of the second transparent electrode layer 207.

By the above-described arrangement, the entire second transparent electrode layer 207 of the present embodiment is embedded in the passivation layer 204 of the non-display region 201, or the passivation layer 301 and the insulating layer 302, so that the stripper can fully contact the entire sidewalls of the patterned mask 202, and make the top surface of the second transparent electrode layer 207 is not higher than the top surface of the passivation layer 204 or 301, and the surface of the non-display region 201 does not remain the second transparent electrode layer 207 that is protruding relative to the upper surface. It is possible to reduce the electrostatic interference caused by the second transparent electrode layer 207 to the non-display region 201 and to the array substrate and the display panel.

The transparent electrode layer is an indispensable part of the array substrate. It is mainly used to provide transparent electrodes to the array substrate. In one application scenario, the transparent electrode layer is indium tin oxide, ITO material. Of course, in other applications, other materials with easy bending, ease of cost reduction and high light transmittance can be used instead of ITO, such as nano zinc oxide.

Step 104: Removing the patterned mask 202 (as illustrated in the fourth figure in FIG. 2).

Compared to the conventional technology, the present embodiment makes the mask to be stripped as patterned type, so that the stripper can pass through all sides of the patterned mask, rather than just through the peripheral sides of the patterned mask. The patterned mask is infiltrated, in such a manner that, the stripping speed of the mask can be improved, and the stripping efficiency of the mask of the array substrate can be remarkably improved, and the production efficiency of the display panel can be improved.

Alternatively, step 104 of the present embodiment specifically includes: infiltrating the stripper on the surface of the mask where the first transparent electrode layer 206 and the second transparent electrode 207 are not covered to stripe the patterned mask 202. The stripper is infiltrating into the patterned mask 202 mainly from the sidewalls of the mask 202, and by reacting with the mask 202 to expand, infiltrating and stripping the mask 202.

Of course, the material of the stripper should match with the material of the mask 202, i.e. the both can produce a reaction to achieve the purpose of stripping rapidly. The specific material or composition of the mask and the stripper is not limited herein.

Alternatively, referring to FIG. 4, FIG. 4 is a schematic structural view of a patterned mask of one embodiment of the present application. The mask of the present embodiment has a plurality of slits 401, the stripper can be in contact with the sidewalls of the mask 402 through the slits 401. Of course, in other embodiments, it is possible to use a recessed groove having other shapes capable of introducing the stripper instead of the slits 401, and the number of the slit 401 can be just one.

Alternatively, the slit 401 of the present embodiment is a continuous slit distributed around the display region 402, and the sides of the slit 401 can be, but are not limited to, parallel to the sidewalls corresponding to the display region 402.

Alternatively, referring to FIG. 5, FIG. 5 is a schematic structural view of a patterned mask of another embodiment of the present application. The slit 501 of the present embodiment is an intermittent slit distributed around the display region 502 and the sides of the slit 501 can be, but are not limited to, parallel to the sidewalls corresponding to the display region 502.

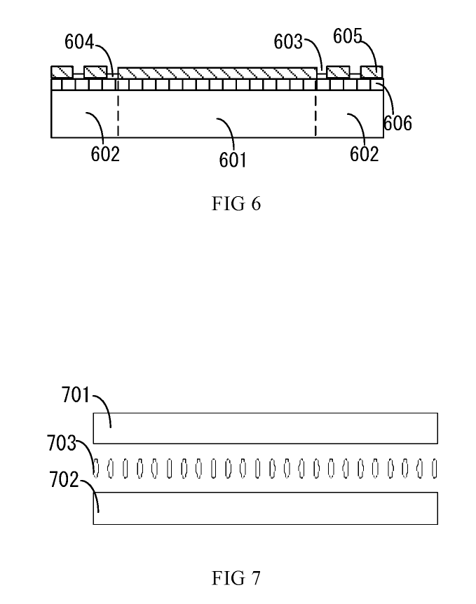

Referring to FIG. 6 and FIG. 6 is a schematic view of an array substrate of one embodiment of the present application. The present embodiment includes a display region 601 and a non-display region 602 disposed around the display region 601. The non-display region is disposed with an etching groove 603, in which a transparent electrode layer 604 is embedded in the etching groove 603. The profile of the etching groove 603 is defined by the patterned mask.

Compared to the conventional technology, the etching groove 603 is disposed in the non-display region 602 of the present embodiment to accommodate the transparent electrode layer 604 produced during the stripping process of the patterned mask, such that the stripper can infiltrate the patterned mask through all sides of the patterned mask, rather than just through the peripheral sides of the patterned mask, to increase the stripping speed of the patterned mask, thereby significantly improving the mask stripping efficiency of the array substrate.

Alternatively, a passivation layer 605 and an insulating layer 606 are disposed from top to bottom on the upper surface of the non-display region 602. The etching grooves are formed on the passivation layer 605 by the above-described patterned mask, and the thickness of the passivation layer 605 is not smaller than the thickness of the transparent electrode layer 604; or is formed on the passivation layer 605 and the insulating layer 606, and the thickness of the passivation layer 605 and the insulating layer 606 is not smaller than the thickness of the transparent electrode layer 604, so that the stripper can fully contact the entire sidewalls of the patterned mask, and the top surface of the transparent electrode layer 604 is not higher than the top surface of the passivation layer 605, and the surface of the non-display region 601 does not remain the transparent electrode layer 604 that is protruding relative to the upper surface. It is possible to reduce the electrostatic interference caused by the transparent electrode layer 604 to the array substrate and the display panel.

Alternatively, the etching groove 603 is distributed continuously or intermittently around the display region 607. The specific distributing manner and shape of the etching grooves 603 have been described in detail in the above-described method embodiments, and are not repeated here.

The principles and process flow of the stripping entire mask of the array substrate have also been described in detail in the above-described method embodiments and are not repeated here.

The display region of the array substrate is not described in the embodiment of the present application, and therefore the drawings in the present application are not marked in detail.

Referring to FIG. 7, FIG. 7 is a schematic structural view of the display panel of one embodiment of the present application. This embodiment includes a first substrate 701, a second substrate 702, and a liquid crystal layer 703. The first substrate 701 and/or the second substrate 702 is the array substrate of the above-mentioned embodiment, wherein the liquid crystal layer 703 is located between the first substrate 701 and the second substrate 702, and the transmittance of the backlight is adjusted under the control of the first substrate 701 and the second substrate 702.

The structure of the array substrate and the principle and the process flow of stripping the mask have been described in detail in the above-described embodiments and are not repeated here.

Compared to the conventional technology, the present embodiment can improve the mask stripping efficiency of the array substrate, thereby improving the manufacturing efficiency of the display panel.

Above are embodiments of the present application, which does not limit the scope of the present application. Any modifications, equivalent replacements or improvements within the spirit and principles of the embodiment described above should be covered by the protected scope of the invention.

What is claimed is:

1. A method for improving the mask stripping efficiency of an array substrate, wherein the array substrate comprising a display region and a non-display region disposed around the display region; a passivation layer and an insulating layer are disposed on the upper surface of the non-display region from top to bottom, comprising:
forming a patterned mask on the non-display region;
etching the passivation layer or the passivation layer and the insulating layer not covered by the patterned mask;
depositing transparent electrode layers to form a patterned first transparent electrode layer and a patterned second electrode layer, respectively on the surface of the patterned mask and the surface of the etched passivation layer or the etched insulating layer; and
infiltrating the surface of the mask not covered by the patterned first transparent electrode layer and the patterned second electrode layer by a stripper to remove the patterned mask.

2. The method according to claim 1, wherein the pattern thickness of the patterned passivation layer, or the pattern thickness of the patterned passivation layer and the patterned insulating layer are not smaller than the thickness of the second transparent electrode layer to make the stripper fully contacting the entire sidewalls of the patterned mask, and make the top surface of the second transparent electrode layer not higher than the top surface of the passivation layer.

3. The method according to claim 1, wherein the patterned mask is the mask having a plurality of slits to makes the stripper contacting the sidewalls of the mask through the slits.

4. The method according to claim 3, wherein the slit is a continuous slit or an intermittent slit distributed around the display region.

5. The method according to claim 1, wherein the transparent electrode layer is indium tin oxide, ITO material.

6. A method for improving the mask stripping efficiency of an array substrate, wherein the array substrate comprising a display region and a non-display region disposed around the display region, comprising:
forming a patterned mask on the non-display region;
etching the portion of the non-display region not covered by the patterned mask;
depositing transparent electrode layers to form a patterned first transparent electrode layer and a patterned second electrode layer, respectively on the surface of the patterned mask and the surface of the etched non-display region; and
removing the patterned mask.

7. The method according to claim 6, wherein the method of removing the patterned mask comprising: infiltrating the surface of the mask not covered by the patterned first transparent electrode layer and the patterned second electrode layer by a stripper to remove the patterned mask.

8. The method according to claim 6, wherein a passivation layer and an insulating layer are disposed on the upper surface of the non-display region from top to bottom, and the passivation layer is located between the insulating layer and the patterned mask; and the method of etching the portion of the non-display region not covered by the patterned mask comprising: etching the passivation layer into a patterned passivation layer, or etching the passivation layer and the insulating layer into the patterned passivation layer and a patterned insulating layer.

9. The method according to claim 8, wherein the pattern thickness of the patterned passivation layer, or the pattern thickness of the patterned passivation layer and the patterned insulating layer are not smaller than the thickness of the second transparent electrode layer to make the stripper fully contacting the entire sidewalls of the patterned mask, and make the top surface of the second transparent electrode layer not higher than the top surface of the passivation layer.

10. The method according to claim 6, wherein the patterned mask is the mask having a plurality of slits to makes the stripper contacting the sidewalls of the mask through the slits.

11. The method according to claim 10, wherein the slit is a continuous slit or an intermittent slit distributed around the display region.

12. The method according to claim 10, wherein the transparent electrode layer is indium tin oxide, ITO material.

13. An array substrate, comprising:
a display region and a non-display region disposed around the display region; an etching groove is disposed in the non-display region, a transparent electrode layer is embedded in the etching groove, and the profile of the etching groove is defined by the patterned mask.

14. The array substrate according to claim 13, wherein a passivation layer and an insulating layer are disposed on the upper surface of the non-display region from top to bottom; the etching grooves are formed on the passivation layer by the patterned mask, and the thickness of the passivation layer is not smaller than the thickness of the transparent electrode layer; or is formed on the passivation layer and the insulating layer, and the thickness of the passivation layer and the insulating layer is not smaller than the thickness of the transparent electrode layer to make the stripper contacting the entire sidewalls of the patterned mask, and make the top surface of the transparent electrode layer not higher than the top surface of the passivation layer.

15. The array substrate according to claim 13, wherein the etching groove is distributed continuously or intermittently around the display region.

16. The array substrate according to claim 13, wherein the transparent electrode layer is indium tin oxide, ITO material.

17. A display panel, comprising:
a first substrate, a second substrate, and a liquid crystal layer, wherein the first substrate and/or the second substrate is the array substrate according to claim 13; and
wherein the liquid crystal layer is located between the first substrate and the second substrate, and the transmittance of a backlight is adjusted under the control of the first substrate and the second substrate.

18. The display panel according to claim 17, wherein a passivation layer and an insulating layer are disposed on the upper surface of the non-display region from top to bottom; the etching grooves are formed on the passivation layer by the patterned mask, and the thickness of the passivation layer is not smaller than the thickness of the transparent electrode layer; or is formed on the passivation layer and the insulating layer, and the thickness of the passivation layer and the insulating layer is not smaller than the thickness of the transparent electrode layer to make the stripper contacting the entire sidewalls of the patterned mask, and make the top surface of the transparent electrode layer not higher than the top surface of the passivation layer.

19. The display panel according to claim 17, wherein the etching groove is distributed continuously or intermittently around the display region.

20. The display panel according to claim 17, wherein the transparent electrode layer is indium tin oxide, ITO material.
